(19) United States
(12) Patent Application Publication
(10) Pub. No.: US 2026/0012171 A1
(43) Pub. Date: Jan. 8, 2026

(54) DRIVING CIRCUIT AND SWITCHING CIRCUIT INCLUDING THE SAME

(71) Applicant: SAMSUNG ELECTRONICS CO., LTD., SUWON-SI (KR)

(72) Inventor: HYUNSEOK NAM, Suwon-si (KR)

(21) Appl. No.: 19/238,615

(22) Filed: Jun. 16, 2025

(30) Foreign Application Priority Data
Jul. 5, 2024 (KR) 10-2024-0089162

(51) Int. Cl. H03K 17/16; H03K 17/284

(52) U.S. Cl. CPC H03K 17/162; H03K 17/284

(57) ABSTRACT

A switching circuit includes a power switch, a first driver configured to drive the power switch based on a first input signal, a delay circuit configured to output a delayed input signal, and a second driver configured to drive the power switch based on the delayed input signal. The first driver has a first driving strength and is configured to drive the power switch in a first stage of operation. The delayed input signal is delayed by a delay value relative to a second input signal. The second driver has a second driving strength higher than the first driving strength and is configured to drive the power switch in a second stage of operation, which is subsequent to the first stage of operation.

### CROSS-REFERENCE TO RELATED APPLICATIONS

This application claims priority under 35 U.S.C. § 119 to Korean Patent Application No. 10-2024-0089162, filed on Jul. 5, 2024, the disclosure of which is incorporated by reference herein in its entirety.

### TECHNICAL FIELD

Example embodiments relate to a driving circuit and a switching circuit including the same.

### DISCUSSION OF RELATED ART

As process technology advances and scales down, power switches may become more susceptible to leakage current. Due to gate leakage current, a driving voltage of the driver may be reduced by resistance connected to a gate of a power switch. The reduced driving voltage may prevent the power switch from being fully turned on. When the power switch is not fully turned on, turn-on resistance of the power switch itself increases, and a voltage drop across a load connected to the power switch may occur.

### SUMMARY

Example embodiments provide a driving circuit that may reduce effects of gate leakage current and a switching circuit including the same.

According to an example embodiment, a switching circuit includes a power switch, a first driver configured to drive the power switch based on a first input signal, a delay circuit configured to output a delayed input signal, and a second driver configured to drive the power switch based on the delayed input signal. The first driver has a first driving strength and is configured to drive the power switch in a first stage of operation. The delayed input signal is delayed by a delay value relative to a second input signal. The second driver has a second driving strength higher than the first driving strength and is configured to drive the power switch in a second stage of operation, which is subsequent to the first stage of operation.

According to an example embodiment, a switching circuit includes a power switch, a first driver configured to drive the power switch based on an input signal, a delay circuit configured to output a delayed input signal, and a second driver configured to drive the power switch based on the delayed input signal. The first driver has a first driving strength and is configured to drive the power switch in a first stage of operation. The delayed input signal is delayed by a delay value relative to the input signal. The second driver has a second driving strength higher than the first driving strength and is configured to drive the power switch in a second stage of operation, which is subsequent to the first stage of operation.

According to an example embodiment, a driving circuit includes a first driver configured to drive a switching signal based on a first input signal, a delay circuit configured to output a delayed input signal, and a second driver configured to drive the switching signal based on the delayed input signal. The first driver has a first driving strength and is configured to drive the switching signal in a first stage of operation. The delayed input signal is delayed by a delay value relative to a second input signal. The second driver has a second driving strength higher than the first driving strength and is configured to drive the switching signal in a second stage of operation, which is subsequent to the first stage of operation.

### BRIEF DESCRIPTION OF THE DRAWINGS

The above and other features of the present disclosure will become more apparent by describing in detail embodiments thereof with reference to the accompanying drawings.

FIG. 1 is a block diagram of a switching circuit according to example embodiments.

FIG. 2 is a block diagram of a switching circuit according to example embodiments.

FIG. 3 is a diagram illustrating a power switch according to example embodiments.

FIG. 4 is a circuit diagram of a switching circuit based on a resistor-capacitor (RC) filter according to example embodiments.

FIG. 5 is a timing diagram of the switching circuit of FIG. 4.

FIG. 6 is a circuit diagram of a switching circuit based on an RC filter according to example embodiments.

FIG. 7 is a timing diagram of the switching circuit of FIG. 6.

FIG. 8 is a circuit diagram of a switching circuit based on an RC filter according to example embodiments.

FIG. 9 is a timing diagram of the switching circuit of FIG. 8.

FIG. 10 is a circuit diagram of a switching circuit operating based on a current-controlled voltage driving scheme, according to example embodiments.

FIG. 11 is a timing diagram of the switching circuit illustrated in FIG. 10.

FIG. 12 is a circuit diagram of a switching circuit operating based on a current-controlled voltage driving scheme, according to example embodiments.

FIG. 13 is a timing diagram of the switching circuit illustrated in FIG. 12.

FIG. 14 is a circuit diagram of a switching circuit operating based on a current-controlled voltage driving scheme, according to example embodiments.

FIG. 15 is a timing diagram of the switching circuit illustrated in FIG. 14.

FIG. 16 is a circuit diagram of a first driver according to example embodiments.

FIGS. 17 and 18 are diagrams illustrating operation waveforms of a switching circuit according to example embodiments.

FIG. 19 is a block diagram of a driving circuit according to example embodiments.

FIG. 20 is a diagram illustrating an electronic device according to example embodiments.

FIG. 21 is a diagram illustrating a mobile terminal according to example embodiments.

### DETAILED DESCRIPTION

Example embodiments of the present disclosure will be described more fully hereinafter with reference to the accompanying drawings. Like reference numerals may refer to like elements throughout the accompanying drawings.

It will be understood that the terms “first,” “second,” “third,” etc. are used herein to distinguish one element from another, and the elements are not limited by these terms. Thus, a “first” element in an example embodiment may be described as a “second” element in another example embodiment.

It should be understood that descriptions of features or aspects within each example embodiment should typically be considered as available for other similar features or aspects in other example embodiments, unless the context clearly indicates otherwise.

As used herein, the singular forms “a”, “an” and “the” are intended to include the plural forms as well, unless the context clearly indicates otherwise.

It will be understood that when a component is referred to as being “on”, “connected to”, “coupled to”, or “adjacent to” another component, it can be directly on, connected, coupled, or adjacent to the other component, or intervening components may be present. It will also be understood that when a component is referred to as being “between” two components, it can be the only component between the two components, or one or more intervening components may also be present. Other words used to describe the relationships between components should be interpreted in a like fashion.

As semiconductor process technology continues to scale down, power switches may face challenges such as, for example, gate leakage current, momentary current, and associated reliability issues. Leakage current can lead to increased turn-on resistance, resulting in insufficient voltage supply to connected loads, while momentary current, caused by the rapid activation of power switches, may induce electromigration and voltage spikes due to parasitic inductance. These issues may compromise the reliable operation of power switches and the systems they power, such as, for example, CPUs and GPUs, especially in high-performance applications.

Example embodiments of the present application provide an improved driving circuit and switching circuit designed to address these issues. Example embodiments may utilize a multi-stage driving approach that sequentially engages a first driver and a second driver, each having distinct driving strengths. For example, the first driver, having a low driving strength and high output impedance, may initiate the power switch's activation gently, reducing the risk of momentary current. A delay circuit then activates the second driver, which has a higher driving strength and lower output impedance, to fully turn on the power switch. This sequential operation may reduce current surges, mitigate the effects of leakage current, and allow the power switch to provide stable voltage to the connected load.

By incorporating a delay mechanism and leveraging the complementary characteristics of the two different drivers, example embodiments of the present application may improve the reliability and performance of power switches in scaled-down semiconductor processes. This configuration may reduce electromigration, voltage fluctuations, and gate voltage instability, providing improved power management circuits. Example embodiments may balance the trade-offs between reducing momentary current and addressing gate leakage, resulting in efficient operation even in advanced implementations.

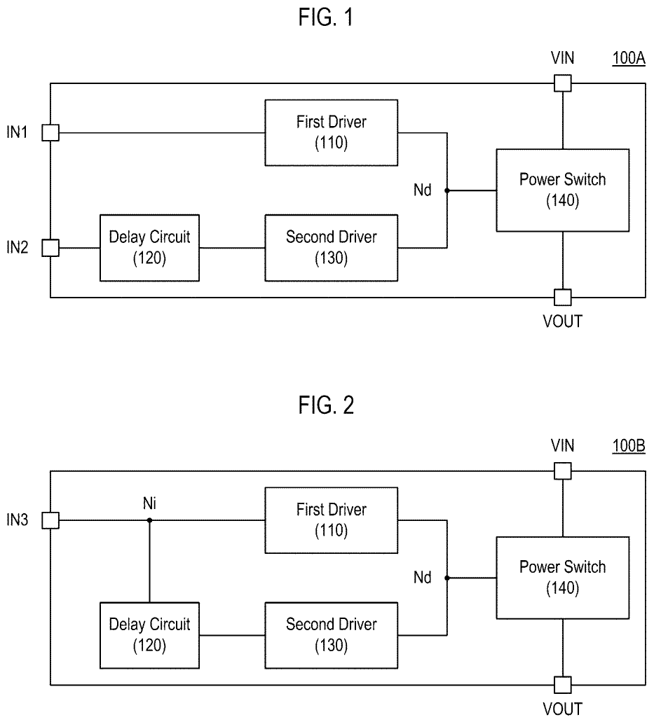

FIG. 1 is a block diagram of a switching circuit according to example embodiments.

Referring to FIG. 1, a switching circuit 100A according to example embodiments may include a first driver 110 (also referred to as a first driver circuit), a delay circuit 120, a second driver 130 (also referred to as a second driver circuit), and a power switch 140. The switching circuit 100A may be configured to drive the first driver 110 and/or the second driver 130 based on two input signals, a first input signal IN1 and a second input signal IN2, and to turn on or off the power switch 140 through the driving.

The second input signal IN2 may be a signal delayed by a set time value from the first input signal IN1. For example, in terms of the switching circuit 100A, the second input signal IN2 may be delayed by a set time value from the first input signal IN1 externally and then applied to the switching circuit 100A. The second input signal IN2 may have the same logic level holding time as the first input signal IN1, except that a transition timing between logic levels (for example, logic high and logic low) is delayed by a set time value compared to the transition timing of the first input signal IN1.

For example, according to example embodiments, the second input signal IN2 is a signal that is delayed from the first input signal IN1 by a predetermined time value. For example, in the context of the switching circuit 100A, the second input signal IN2 may undergo an external delay corresponding to the set time value relative to the first input signal IN1 before being supplied to the switching circuit 100A. While the second input signal IN2 retains the same logic level duration as the first input signal IN1, the timing of its transitions between logic levels (e.g., logic high to logic low or vice versa) is offset by the set time value relative to the transition timing of the first input signal IN1.

According to example embodiments, a time at which the second driver 130 starts operating together with the first driver 110 may be adjusted depending on the magnitude of the set time value for delaying the second input signal IN2.

The first driver 110 and the second driver 130 drive the power switch 140 according to the driving strength. The driving strength may be defined as a strength for driving a voltage level of an output signal in a specific direction, and the greater the driving strength, the more the voltage level of the output signal increases in the specific direction.

A magnitude of output impedance of the driver may vary depending on a magnitude of the driving strength. For example, a driver configured to have a low driving strength may have a high output impedance, while a driver configured to have a high driving strength may have a low output impedance.

According to example embodiments, the first driver 110 may be configured to drive the power switch 140 based on the first input signal IN1 and to have a first driving strength. For example, the first driver 110 may have a high output impedance. An output terminal of the first driver 110 may be connected to a driving node Nd to which the power switch 140 is connected.

The delay circuit 120 may be configured to output a delayed input signal that is a delayed version of the second input signal IN2 by a delay value. The delay value may be a predetermined delay value relative to the second input signal IN2. Thus, the delayed input signal may be delayed by a predetermined delay value relative to the second input signal IN2. The delay value may be distinguished from the set time value for the second input signal IN2. For example, the delayed input signal may be regarded as a signal delayed by at least the set time value and the delay value of the first input signal IN1. Similarly to the set time value, a time at which the second driver 130 starts operating together with the first driver 110 may be adjusted depending on the magnitude of the delay value.

According to example embodiments, the magnitude of the delay value may be adjusted through the delay circuit 120.

In example embodiments, the second driver 130 may be configured to drive the power switch 140 based on the delayed input signal and to have a second driving strength higher than the first driving strength. For example, the second driver 130 has a low output impedance. An input terminal of the second driver 130 may be connected to an output terminal of the delay circuit 120, and an output terminal of the second driver 130 may be connected to the driving node Nd.

The power switch 140 may operate based on the input voltage VIN and may be connected to the driving node Nd. The input voltage VIN may be the same as or different from a supply voltage, not illustrated, operating the first driver 110 and the second driver 130. The power switch 140 may be turned on or off depending on the driving of the first driver 110 and/or the second driver 130. When the power switch 140 is turned on, an output voltage VOUT may be output from the power switch 140. When the power switch 140 is connected to a load, not illustrated, the output voltage VOUT may be applied to the load.

According to example embodiments, the first driver 110 and the second driver 130 may be configured to slightly turn on or off the power switch 140. For example, the first driver 110 and the second driver 130 may be configured based on an RC filter or may be configured to operate in a current-controlled voltage driving scheme.

Herein, when the power switch 140 is described as being “slightly” turned on or off, it is to be understood that the power switch 140 may be partially turned on or off (e.g., partially activated or deactivated) rather than being fully/completely turned on or off. For example, as used herein, the term “partially” may refer to a state of activation of the power switch 140 where the activation is intentionally limited to an intermediate or incomplete level. This state may be characterized by, for example, reduced current flow, a gradual increase in gate voltage, or operation constrained by the driving strength or output impedance of the first driver 110. Similarly, the term “slightly” may refer to a restrained activation of the power switch 140 that aligns with the concept of partial activation. For example, the first driver 110, having a lower driving strength and higher output impedance compared to the second driver 130, may “slightly” or “partially” activate the power switch 140 by precharging the gate voltage to a level sufficient to initiate limited current flow without fully turning on the power switch 140.

When the power switch 140 is rapidly turned on, momentary current may flow to a load, not illustrated, connected to the power switch 140. The momentary current may cause electromigration and may generate a high input voltage VIN through parasitic inductance of a metal line to which the input voltage VIN is applied. Due to the issues caused by the momentary current, the reliability of turning on or off the power switch 140 may be deteriorated.

When the first driver 110 and the second driver 130 are configured to slightly turn on or off the power switch 140 according to example embodiments described above, the issues caused by the momentary current may be addressed.

In some cases, leakage current flowing from the input voltage VIN toward the driving node Nd may be generated in the power switch 140. Such leakage current may increase as a semiconductor process scales down. Alternatively, the leakage current may also be generated even when the first driver 110 and the second driver 130 are configured to slightly drive the power switch 140 according to example embodiments described above.

When leakage current is generated, the turn-on resistance of the power switch 140 may be increased to decrease the output voltage VOUT supplied to the load, not illustrated, that may be connected to the power switch 140.

According to example embodiments, the switching circuit 100A may sequentially operate the first driver 110 and the second driver 130 to decrease the leakage current. The power switch 140 may be first driven through the first driver 110, for example, during a first stage of operation. By driving the first driver 110, the power switch 140 may be slightly turned on. Then, the delayed input signal may cause the second driver 130 to start operating after a certain amount of delay, compared to the first driver 110. The first driver 110 and the second driver 130 may drive the power switch 140 together to fully turn on the power switch 140, for example, in a second stage of operation subsequent to the first stage of operation.

Despite generation of leakage current in the power switch 140 when the first driver 110 and the second driver 130 operate together, effects of the leakage current may be reduced due to the second driver 130 having a low output impedance. For example, in example embodiments, the leakage current may flow to the second driver 130 having a low output impedance. As a result, the turn-on resistance of the power switch 140 is not increased. Accordingly, despite generation of the leakage current, a voltage at a driving node Nd may be maintained at a voltage level for turning on the power switch 140.

According to example embodiments described above, the switching circuit 100A may slightly turn on the power switch 140 by operating the first driver 110 to prevent the issues caused by the momentary current, and reduce the effects of the leakage current by then operating the second driver 130 together with the first driver 110 through the delay circuit 120.

For example, according to example embodiments, the timing at which the second driver 130 begins to operate in conjunction with the first driver 110 can be adjusted based on the magnitude of the set time value used to delay the second input signal IN2. The first driver 110 and the second driver 130 are responsible for driving the power switch 140, with their operation determined by their respective driving strengths. Driving strength refers to the capability of a driver to influence the voltage level of an output signal in a particular direction. The greater the driving strength, the more effectively the voltage level of the output signal changes in that direction. The output impedance of a driver may depend on its driving strength. For example, a driver with low driving strength may have high output impedance, while a driver with high driving strength may have low output impedance.

In example embodiments, the first driver 110 is configured to drive the power switch 140 based on the first input signal IN1, operating with a first driving strength. This first driver 110 may have a high output impedance, and its output terminal is connected to a driving node Nd, which interfaces with the power switch 140. The delay circuit 120 may generate a delayed input signal by delaying the second input signal IN2 by a specific delay value. This delay value may be distinct from the set time value of the second input signal IN2. For example, the delayed input signal may correspond to a signal delayed by at least the combined duration of the set time value and the delay value relative to the first input signal IN1. Similar to the set time value, the delay value may determine the timing at which the second driver 130 operates in conjunction with the first driver 110. The delay value may be adjusted through the delay circuit 120.

According to example embodiments, the second driver 130 may drive the power switch 140 based on the delayed input signal and operate with a second driving strength greater than the first driving strength. The second driver 130, which has a low output impedance, may connect its input terminal to the output of the delay circuit 120, and its output terminal to the driving node Nd.

The power switch 140 may operate based on the input voltage VIN and connect to the driving node Nd. The input voltage VIN may either match or differ from the supply voltage used by the first driver 110 and the second driver 130. Depending on the drivers' operation, the power switch 140 can be turned on or off. When the power switch 140 is turned on, an output voltage VOUT is supplied, which can power a connected load. The first driver 110 and the second driver 130 may be configured to slightly turn the power switch 140 on or off. These drivers may be designed using an RC filter or operate in a current-controlled voltage driving scheme.

Rapid activation of the power switch 140 can result in momentary current flow to the connected load. This surge of current may cause electromigration or generate a high input voltage VIN due to parasitic inductance in the metal line supplying VIN. As a result, the reliability of the power switch's 140 operation may be decreased. By configuring the first driver 110 and the second driver 130 to activate the power switch 140 gradually, example embodiments may mitigate this decrease in reliability.

In some cases, leakage current may flow from the input voltage VIN toward the driving node Nd through the power switch 140. This leakage current may increase with process miniaturization and may occur even when the drivers are configured for slight operation of the power switch 140. Leakage current can raise the turn-on resistance of the power switch 140, which may reduce the output voltage VOUT supplied to a connected load and cause operational issues. To address leakage current, according to example embodiments, the switching circuit 100A may sequentially operate the first driver 110 and the second driver 130. Initially, the first driver 110 may activate the power switch 140 slightly. Then after a certain delay, the delayed input signal may trigger the second driver 130, allowing both drivers to work together to fully activate the power switch 140.

As a result, even when leakage current is present, its effects may be reduced because the second driver 130, with its low output impedance, may allow the leakage current to flow through it without increasing the turn-on resistance of the power switch 140. As a result, the voltage at the driving node Nd may remain at a level sufficient to activate the power switch 140.

Thus, according to example embodiments, the switching circuit 100A may prevent or reduce momentary current issues by employing the first driver 110 for slight activation, while the combined operation of the first driver 110 and the second driver 130, coordinated by the delay circuit 120, may reduce the effects of leakage current.

FIG. 2 is a block diagram of a switching circuit according to example embodiments.

Referring to FIG. 2, a switching circuit 100B according to example embodiments may operate based on a single input signal (a third input signal IN3), unlike an embodiment illustrated in FIG. 1. For example, the third input signal IN3 may be applied to a first driver 110 and a delay circuit 120 through an input node N1. Input terminals of the first driver 110 and the delay circuit 120 may be connected to the input node N1 and may operate based on the third input signal IN3.

For example, the third input signal IN3 may have a waveform transitioning between logic low and logic high to operate the first driver 110, similarly to the first input signal IN1 of FIG. 1. The first driver 110 may drive the power switch 140 based on the third input signal IN3.

In the case of the second driver 130, a signal delayed from the same input signal (for example, the third input signal IN3) may be used, unlike an embodiment illustrated in FIG. 1. For example, the delay circuit (120) may output a delayed input signal where the third input signal (IN3), which is the same as a signal applied to the first driver 110, is delayed by a certain delay value.

The second driver 130 may drive the power switch 140 based on the delayed input signal. Similarly to FIG. 1, the second driver 130 may be configured to have a second driving strength higher than the first driving strength of the first driver 110, and thus may have a lower output impedance than the first driver 110. Therefore, according to example embodiments, when the first driver 110 slightly turns on the power switch 140 and then the second driver 130 fully turns on the power switch 140 together with the first driver 110, the effects of the momentary current and leakage current associated with the power switch 140 may be reduced.

Moreover, in the case of an embodiment according to FIG. 2, only one input signal is used to operate the first driver 110 and the second driver 130. As a result, a timing at which the second driver 130 operates after the operation of the first driver 110 is entirely determined through the delay circuit 120. In addition, only one input signal is used. As a result, implementation complexity of the switching circuit 100B may be reduced.

For example, according to example embodiments, the second driver 130 is configured to drive the power switch 140 based on the delayed input signal. Similar to the configuration in FIG. 1, the second driver 130 is designed with a higher driving strength than the first driver 110, resulting in a lower output impedance compared to the first driver 110. According to example embodiments, the first driver 110 initially activates the power switch 140 slightly, and subsequently, the second driver 130 fully activates the power switch 140 in conjunction with the first driver 110. This sequential operation may mitigate the effects of both momentary current and leakage current associated with the power switch 140.

In the configuration shown in FIG. 2, a single input signal is used to control both the first driver 110 and the second driver 130. The timing of the second driver's 130 operation, relative to the first driver 110, is determined entirely by the delay circuit 120. The use of a single input signal may simplify the implementation of the switching circuit 100B, which may reduce overall complexity.

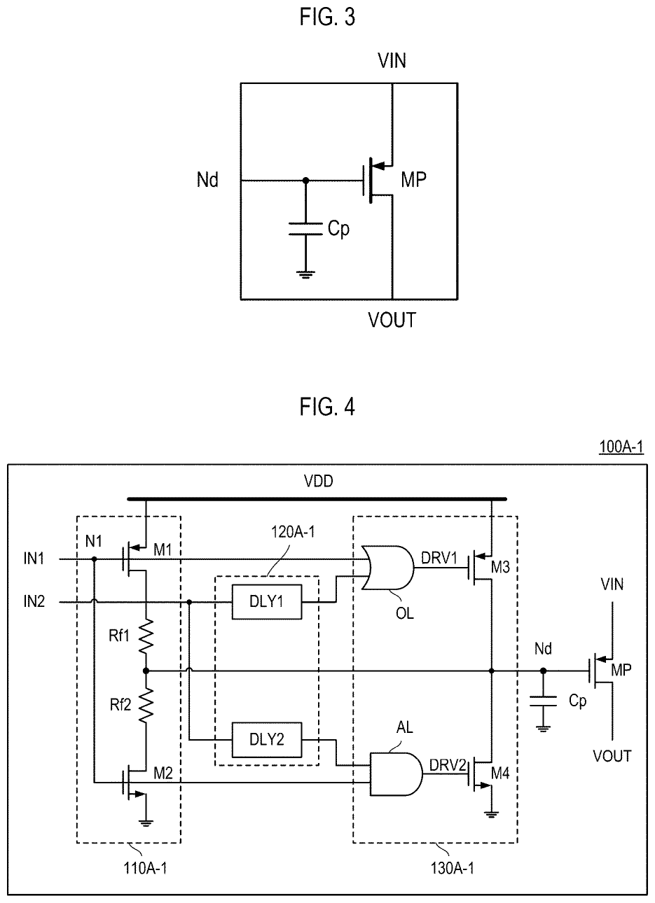

FIG. 3 is a diagram illustrating a power switch according to example embodiments.

Referring to FIG. 3, a power switch MP according to example embodiments may be implemented with a P-type metal-oxide-semiconductor field effect transistor (PMOSFET), a type of P-channel transistor. In this case, the input voltage VIN may be applied to a source of the power switch MP, and the output voltage VOUT may be output through a drain of the power switch MP. The output voltage VOUT may be output through the driving of the first driver 110 and/or the second driver 130 according to embodiments as described above. A gate of the power switch MP may be connected to a driving node Nd connected to the first driver 110 and the second driver 130.

A parasitic capacitance component Cp may appear at the driving node Nd due to the power switch MP (or various configurations that may be included in the switching circuit). When the first driver 110 and the second driver 130 are configured to slightly operate the power switch MP according to example embodiments described above, the power switch MP may be configured as an RC filter including a parasitic capacitance component Cp on the side of the driving node Nd. The power switch MP may be turned on or off more slightly due to the parasitic capacitance component Cp.

According to example embodiments, the power switch MP may be implemented with various switching elements such as, for example, an N-type transistor and a bipolar junction transistor (BJT), as well as the above-mentioned PMOS. However, for ease of description, the power switch MP will be described as a PMOS in the present application.

FIG. 4 is a circuit diagram of a switching circuit based on an RC filter according to example embodiments.

Referring to FIG. 4, a switching circuit 100A-1 according to example embodiments may be configured based on an RC filter. For example, the switching circuit 100A-1 may include a parasitic capacitance component Cp, connected to a driving node Nd, and feedback resistors Rf1 and Rf2 forming an RC filter. The feedback resistors Rf1 and Rf2 may be included in a first driver 110A-1.

The switching circuit 100A-1 according to example embodiments may have a symmetrical structure configured based on two input signals (a first input signal IN1 and a second input signal IN2).

The first driver 110A-1 may include a first feedback resistor Rf1 and a second feedback resistor Rf2 connected to the driving node Nd, a first switch M1, and a second switch M2. For example, the first switch M1 may be implemented as a P-type transistor, and the second switch M2 may be implemented as an N-type transistor.

The first switch M1 may have a source applied with a supply voltage VDD, a gate applied with the first input signal, and a drain connected to the first feedback resistor Rf1. The second switch M2 may have a drain connected to the second feedback resistor Rf2, a gate applied with the first input signal IN1, and a source grounded.

According to example embodiments, when the first switch M1 is turned on, the first driver 110A-1 may perform a pull-up driving operation on the driving node Nd through the first feedback resistor Rf1. Alternatively, when the second switch M2 is turned on, the first driver 110A-1 may perform a pull-down driving operation on the driving node Nd through the second feedback resistor Rf2. Regardless of which driving operation is performed, slight driving of the power switch MP may be performed due to the presence of the feedback resistors Rf1 and Rf2 and the parasitic capacitance component Cp. For example, a gate voltage of the power switch MP may increase or decrease with an exponential characteristic.

For example, in example embodiments, when the first switch M1 is turned on, the first driver 110A-1 performs a pull-up driving operation on the driving node Nd via the first feedback resistor Rf1. Conversely, when the second switch M2 is turned on, the first driver 110A-1 performs a pull-down driving operation on the driving node Nd through the second feedback resistor Rf2. In either case, the presence of the feedback resistors Rf1 and Rf2, along with the parasitic capacitance component Cp, may result in a slight driving effect on the power switch MP. For example, the gate voltage of the power switch MP may increase or decrease in an exponential manner.

The second driver 130A-1 may be connected to a delay circuit 120A-1, and the delay circuit 120A-1 may output a delayed input signal to the second driver 130A-1 from the second input signal IN2. Due to the symmetrical structure, the delay circuit 120A-1 may have two delay cells DLY1 and DLY2.

The second driver 130A-1 may include an OR gate OL, an AND gate AL, a third switch M3, and a fourth switch M4. For example, the third switch M3 may be implemented as a P-type transistor, and the fourth switch M4 may be implemented as an N-type transistor.

The OR gate OL may output a first drive signal DRV1 through an OR operation on the first input signal IN1 and the delayed input signal. The AND gate AL may output a second drive signal DRV2 through an AND operation on the first input signal IN1 and the delayed input signal.

The third switch M3 may have a source applied with a supply voltage VDD, a gate applied with the first drive signal DRV1, and a drain connected to the driving node Nd. The fourth switch M4 may have a drain connected to the driving node Nd, a gate applied with the second drive signal DRV2, and a source grounded.

According to example embodiments, when the third switch M3 is turned on, the second driver 130A-1 may perform a pull-up driving operation on the driving node Nd. Alternatively, when the fourth switch M4 is turned on, the second driver 130A-1 may perform a pull-down driving operation on the driving node Nd. Regardless of which driving operation is performed, slight driving of the power switch MP may be performed due to the presence of the parasitic capacitance component Cp.

According to example embodiments, the third switch M3 and the fourth switch M4 may be implemented to have larger sizes than the first switch M1 and the second switch M2. An output impedance of the second driver 130A-1 including the third switch M3 and the fourth switch M4 implemented to have larger sizes may be lower than an output impedance of the first driver 110A-1. Therefore, the second driver 130A-1 may have a second driving strength.

A description will now be provided for a driving operation of the first driver 110A-1 and the second driver 130A-1. When the power switch MP is to be turned on, the first driver 110A-1 may slightly turn on the power switch MP based on the first input signal IN1 being logic high and the second input signal IN2 being logic low, according to example embodiments.

Then, the first driver 110A-1 and the second driver 130A-1 may fully turn on the power switch MP based on the first input signal IN1 and the second input signal IN2 being logic high and the second input signal IN2 transitioning to logic high after a time lapse of a delay value or more.

Next, when the power switch MP is to be turned off, the first driver 110A-1 may slightly turn off the power switch MP based on the first input signal IN1 being logic low and the second input signal IN2 being logic high, according to example embodiments.

Then, the first driver 110A-1 and the second driver 130A-1 may fully turn off the power switch MP based on the first input signal IN1 and the second input signal IN2 being logic low and the second input signal IN2 transitioning to logic low after a time lapse of the delay value or more.

The switching circuit 100A-1 according to example embodiments described above may be configured based on an RC filter to slightly drive the power switch MP. In addition, the effects of the leakage current of the power switch MP may be reduced due to the second driver 130A-1 having a lower output impedance.

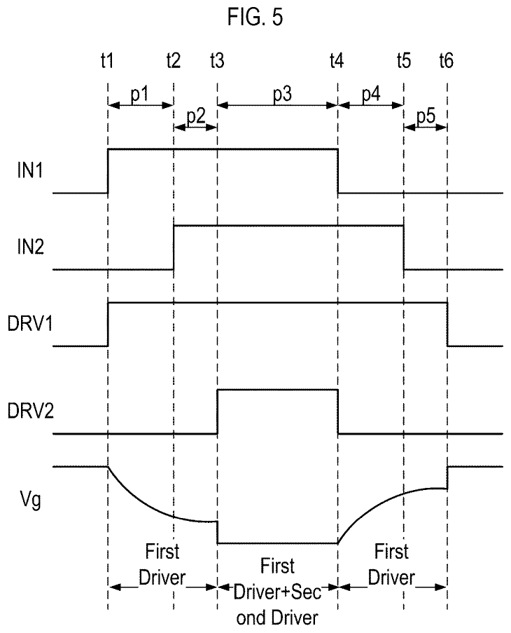

FIG. 5 is a timing diagram of the switching circuit of FIG. 4.

Referring to FIGS. 4 and 5, prior to time t1, both the first input signal IN1 and the second input signal IN2 were at logic low, causing the first switch M1 to turn on. As a result, the gate voltage Vg at the driving node Nd was precharged to a specific voltage.

At time t1, the first input signal IN1 may transition to logic high. At time t2, the second input signal IN2 may transition to logic high. A delay gap p1 between input signals may be considered as a set time value for the second input signal IN2. At p1, the first drive signal DRV1 goes high. As a result, only the second switch M2 may be turned on. Accordingly, a gate voltage Vg may slightly decrease, and the power switch MP may be slightly turned on.

The second driver signal DRV2 may go high after a delay of p2 from the first input signal IN1. The gap p2 may have a size that is greater than or equal to the delay value through the delay circuit 120A-1. During p1 and p2, only the first driver 110A-1 may operate. This time period may be referred to as a first stage of operation. Thus, according to example embodiments, only the first driver 110-A1 may drive the power switch MP in a first stage of operation.

After time t3, the second drive signal DRV2 is logic high. As a result, the fourth switch M4 may be turned on together with the second switch M2. Accordingly, the gate voltage Vg may go low, and the power switch MP may be fully turned on. During p3, the first driver 110A-1 and the second driver 130A-1 may drive the power switch MP together. This time period may be referred to as a second stage of operation, which is subsequent to the first stage of operation. Thus, according to example embodiments, both the first driver 110A-1 and the second driver 130A-1 may drive the power switch MP together in a second stage of operation.

At time t4, the first input signal IN1 may transition to logic low, and thus the second drive signal DRV2 may also transition to logic low. During p4, only the first switch M1 may be turned on. As a result, the power switch MP may be slightly turned off.

At time t5, the second input signal IN2 may also transition to logic low. After a gap of p5, the first drive signal DRV1 may transition to logic low. Therefore, after time t6, the first switch M1 and the third switch M3 may be turned on. As a result, the gate voltage Vg may go high, and the power switch MP may be fully turned off.

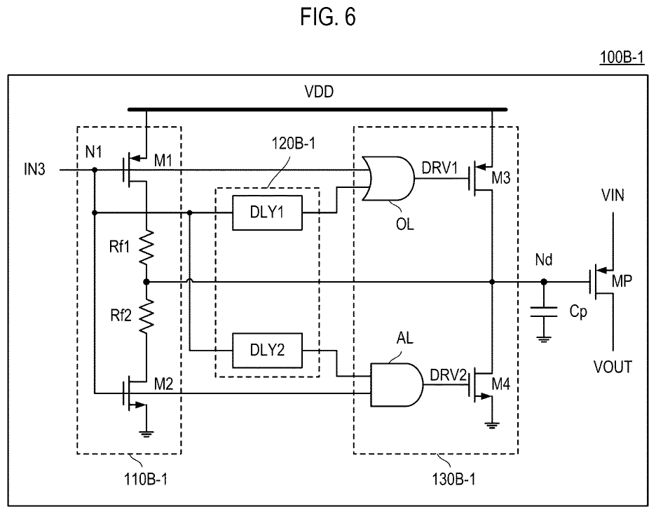

FIG. 6 is a circuit diagram of a switching circuit based on an RC filter according to example embodiments.

Referring to FIG. 6, the switching circuit 100B-1 according to example embodiments may drive a power switch MP based on a third input signal IN3.

For example, the third input signal IN3 may be commonly applied to gates of the first switch M1 and the second switch M2 through the first node N1. For example, the first switch M1 may have a source applied with a supply voltage VDD, a gate applied with the third input signal IN3, and a drain connected to a first feedback resistor Rf1. Also, the second switch M2 may have a drain connected to a second feedback resistor Rf2, a gate applied with the third input signal IN3, and a source grounded.

The third input signal IN3 may also be commonly applied to each of the delay cells DLY1 and DLY2 included in a delay circuit 120B-1. Accordingly, an OR gate OL may output a first drive signal DRV1 through an OR operation on the third input signal IN3 and a delayed input signal, and an AND gate AL may output a second drive signal DRV2 through an AND operation on the third input signal IN3 and the delayed input signal.

According to example embodiments, the first driver 110B-1 may slightly turn on the power switch MP based on an input signal transitioning to logic high. Then, the first driver 110B-1 and the second driver 130B-1 may fully turn on the power switch MP based on the input signal transitioning to logic high after a time lapse of a delay value or more.

The switching circuit 100B-1 according to example embodiments described above may drive the power switch MP through the common third input signal IN3. Accordingly, even though the number of applied signals is reduced to one, sequential driving of the first driver 110B-1 and the second driver 130B-1 may be performed through the delay circuit 120B-1. As a result, the switching circuit 100B-1 may reduce the effects of transient current and leakage current.

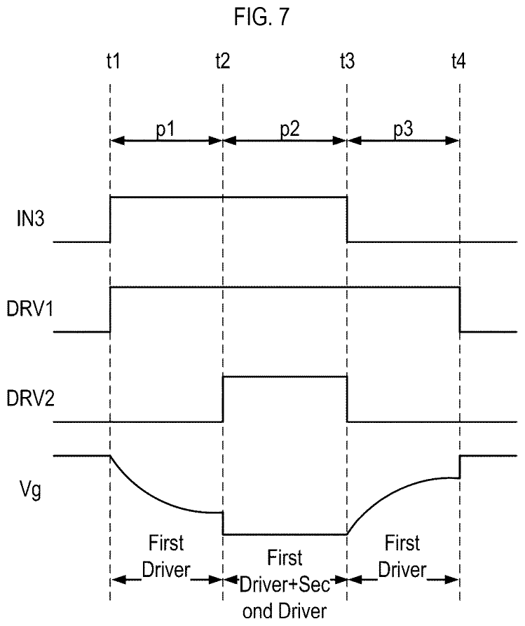

FIG. 7 is a timing diagram of the switching circuit of FIG. 6. For convenience of explanation in the following descriptions, reference numerals corresponding to time values in each timing diagram may be reused. While the same reference numerals may represent identical time values in some instances, they may also denote different time values depending on the context.

Referring to FIGS. 6 and 7, before time t1, the third input signal IN3 was logic low, the first switch M1 was turned on, and the gate voltage Vg, which is a voltage at a driving node Nd, was precharged to a certain voltage.

At time t1, the third input signal IN3 may transition to logic high. At p1, a first drive signal DRV1 may go high. As a result, only a second switch M2 may be turned on. As a result, a gate voltage Vg may slightly decrease, and the power switch MP may be slightly turned on.

A second drive signal DRV2 may go high at time t2 after a delay of p1 from the first input signal IN1. The gap p2 may have a size that is greater than or equal to the delay value through the delay circuit 120B-1.

After time t2, the second drive signal DRV2 may be logic high. As a result, a fourth switch M4 may be turned on together with the second switch M2. Accordingly, the gate voltage Vg may go low, and the power switch MP may be fully turned on. During p2, the first driver 110B-1 and the second driver 130B-1 may drive the power switch MP together.

At time t3, the third input signal IN3 may transition to logic low, and thus the second drive signal DRV2 may also transition to logic low. During p3, only the first switch M1 may be turned on. As a result, the power switch MP may be slightly turned off.

At time t4 following time t3 after a gap of p3, the first drive signal DRV1 may transition to logic low. Accordingly, after time t4, the first switch M1 and the third switch M3 may be turned on. As a result, the gate voltage Vg may go high, and the power switch MP may be fully turned off.

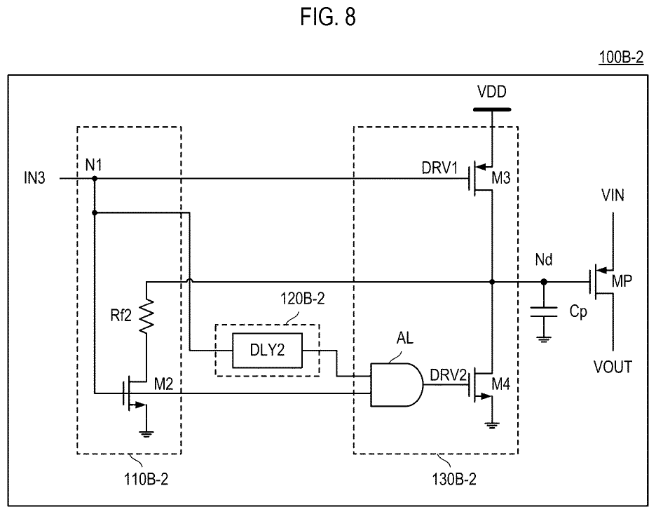

FIG. 8 is a circuit diagram of a switching circuit based on an RC filter according to example embodiments.

Referring to FIG. 8, a switching circuit 100B-2 according to example embodiments may be configured to have an asymmetrical structure, unlike the switching circuit having the symmetrical structure of FIG. 6.

For example, the first driver 110B-2 may include a second feedback resistor Rf2, connected to a driving node Nd, and a second switch M2. The second switch M2 may have a drain connected to the second feedback resistor Rf2, a gate applied with a third input signal IN3 through the first node N1, and a source grounded.

Due to the asymmetrical structure, the delay circuit 120B-2 may include only one delay cell DLY2.

The second driver 130B-2 may include an AND gate AL, a third switch M3, and a fourth switch M4. The AND gate AL may output a second drive signal DRV2 through an AND operation on the third input signal IN3 and a delayed input signal. The second drive signal DRV2 may be applied to a gate of the fourth switch M4.

In the asymmetrical structure, the third input signal IN3 may be directly applied to the gate of the third switch M3. The third switch M3 may have a source applied with a supply voltage VDD and a drain connected to a driving node Nd.

The fourth switch M4 may have a drain connected to the driving node Nd, a gate applied with the second drive signal DRV2, and a source grounded.

Even with the asymmetrical structure, a turn-on operation of at least the power switch MP may be the same as that in the symmetrical structure. For example, the second switch M2 of the first driver 110B-2 may slightly turns on the power switch MP, and then the fourth switch M4 of the second driver 130B-2 may fully turn on the power switch MP together. Only the turn-off operation is different. In the turn-off operation, only the second driver 130B-2 may drive the power switch MP.

According to example embodiments described above, the switching circuit 100B-2 may reduce the implementation complexity through the asymmetrical structure while reducing the effects of momentary current and leakage current on the power switch MP.

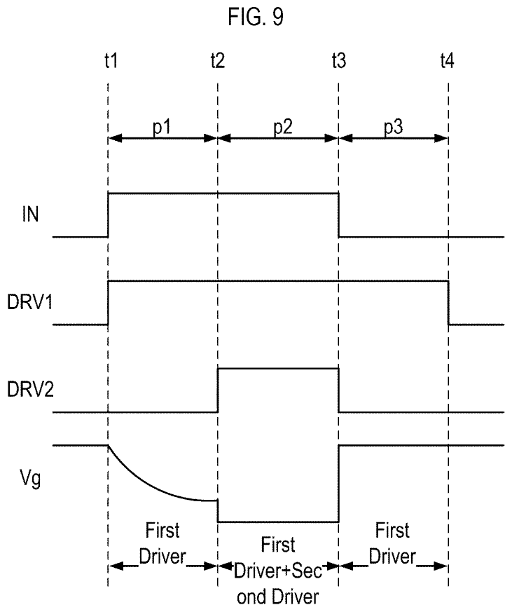

FIG. 9 is a timing diagram of the switching circuit of FIG. 8.

Referring to FIGS. 8 and 9, an operation of turning on the power switch MP is the same as that of FIG. 7. Before time t1, a gate voltage Vg, which is a voltage at the driving node Nd, may be precharged to a certain voltage.

At time t1, the third input signal IN3 may transition to logic high. At p1, the first drive signal DRV1 may go to high. As a result, only the second switch M2 may be turned on. Accordingly, the gate voltage Vg may slightly decrease, and the power switch MP may be slightly turned on. At time t2 after a gap of p1 from the first input signal IN1, the second drive signal DRV2 may go high. At p2, the fourth switch M4 may be turned on together with the second switch M2. Accordingly, the gate voltage Vg may go low, and the power switch MP may be fully turned on.

At time t3, the third input signal IN3 may transition to logic low, and thus the second drive signal DRV2 may also transition to logic low. Unlike what is illustrated in FIG. 7, only the third switch M3 of the second driver 130B-2 may be turned on during p3. As a result, the power switch MP may be immediately fully turned off. At time t4 following time t3 after a gap of p3, the first drive signal DRV1 may transition to logic low.

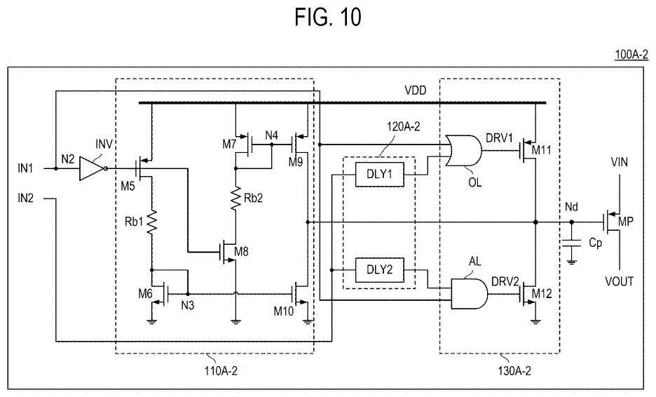

FIG. 10 is a circuit diagram of a switching circuit operating based on a current-controlled voltage driving scheme, according to example embodiments.

Referring to FIG. 10, a switching circuit 100A-2 according to example embodiments may be configured based on a current-controlled voltage driving scheme. For example, the switching circuit 100A-2 may drive a gate voltage of the power switch MP through current control.

The switching circuit 100A-2 according to example embodiments may have a symmetrical structure configured based on two input signals (a first input signal IN1 and a second input signal IN2).

The switching circuit 100A-2 may include a first driver 110A-2, a delay circuit 120A-2, a second driver 130A-2, a power switch MP, and a NOT gate INV (also referred to as an inverter). The NOT gate INV may invert and output a phase of the first input signal IN1, applied through the second node N2.

The first driver 110A-2 may be connected to an output terminal of the NOT gate INV and may include resistors Rb1 and Rb2 and fifth to tenth switches M5 to M10. For example, the fifth switch M5, the seventh switch M7, and the ninth switch M9 may be implemented as P-type transistors, and the sixth switch M6, the eighth switch M8, and the tenth switch M10 may be implemented as N-type transistors.

The fifth switch M5 may have a source applied with a supply voltage VDD, a gate connected to the NOT gate INV, and a drain connected to the first bias resistor Rb1. The inverted first input signal IN1 may be applied to the gate of the fifth switch M5.

The sixth switch M6 may have a drain and a gate, connected to the first bias resistor Rb1, and a source grounded.

The seventh switch M7 may have a source applied with a supply voltage VDD and a gate and a drain connected to the second bias resistor Rb2.

The eighth switch M8 may have a drain connected to the second bias resistor Rb2, a gate connected to the NOT gate INV, and a source grounded. The inverted first input signal IN1 may be applied to the gate of the eighth switch M8.

The ninth switch M9 may have a source applied with a supply voltage VDD, a gate connected to the second bias resistor Rb2, and a drain connected to a driving node Nd. The seventh switch M7 and the ninth switch M9 may be connected to each other through a fourth node N4. The ninth switch M9 may flow a mirrored version of current flowing through the second bias resistor Rb2 to the driving node Nd.

The tenth switch M10 may have a drain connected to the driving node Nd, a gate connected to the first bias resistor Rb1, and a source grounded. The gates of the sixth switch M6 and the tenth switch M10 may be connected to each other through a third node N3. The drains of the ninth switch M9 and the tenth switch M10 may be connected to the driving node Nd. The tenth switch M10 may flow a mirrored version of current flowing through the first bias resistor Rb1 to the ground.

In example embodiments as described above, the fifth switch M5, the sixth switch M6, and the tenth switch M10 may perform a pull-down driving operation on the power switch MP. When the first input signal IN1 is logic high, a pull-down driving operation may be performed as the fifth switch M5 is turned on due to the NOT gate INV. A voltage at the driving node Nd, to which the gate of the power switch MP is connected, may slightly decrease due to the current generated by the fifth switch M5, the sixth switch M6, and the tenth switch M10. Accordingly, the power switch MP may be slightly turned on through the first driver 110A-2.

The seventh switch M7, the eighth switch M8, and the ninth switch M9 may perform a pull-up driving operation on the power switch MP. When the first input signal IN1 is logic low, a pull-up driving operation may be performed as the eighth switch M8 is turned on due to the NOT gate INV. A voltage at the driving node Nd, to which the gate of the power switch MP is connected, may be slightly increased due to the current generated by the seventh switch M7, the eighth switch M8, and the ninth switch M9. Accordingly, the power switch MP may be slightly turned off through the first driver 110A-2.

The delay circuit 120A-2 may include delay cells DLY1 and DLY2 in a symmetrical structure, and the first delay cell DLY1 may delay the second input signal IN2 and apply the delayed second input signal to an OR gate OL, and the second delay cell DLY2 may delay the second input signal IN2 and apply the delayed second input signal to the AND gate AL.

The second driver 130A-2 may be configured and operated in the same manner as examples of the above-described switching circuit 100A-2 based on an RC filter (for example, FIGS. 4 and 5). The OR gate OL may output a first drive signal DRV1 through an OR operation on the first input signal IN1 and the delayed input signal. The AND gate AL may output a second drive signal DRV2 through an AND operation on the first input signal IN1 and the delayed input signal.

The eleventh switch M11 may have a source applied with a supply voltage VDD, a gate applied with the first drive signal DRV1, and a drain connected to the driving node Nd. The twelfth switch M12 may have a drain connected to the driving node Nd, a gate applied with the second drive signal DRV2, and a source grounded. The eleventh switch M11 may perform a pull-up driving operation, and the twelfth switch M12 may perform a pull-down driving operation.

According to example embodiments, the eleventh switch M11 and the twelfth switch M12 may be implemented to have a larger size than the fifth to tenth switches M5 to M10. An output impedance of the second driver 130A-2 may be lower than an output impedance of the first driver 110A-2.

During an operation of turning or off the power switch MP, the first driver 110A-2 may slightly drive the power switch MP, and then fully drive the power switch MP together with the second driver 130A-2. The first driver 110A-2 may drive the gate voltage at the driving node Nd based on current control. As a result, the gate voltage of the power switch MP may increase or decreases linearly, unlike the switching circuit based on an RF filter.

The switching circuit 100A-2 according to example embodiments described above may be configured based on a current-controlled voltage-driven manner to slightly drive the power switch MP. In addition, the effects of the leakage current of the power switch MP may be reduced due to the second driver 130A-2 having a lower output impedance

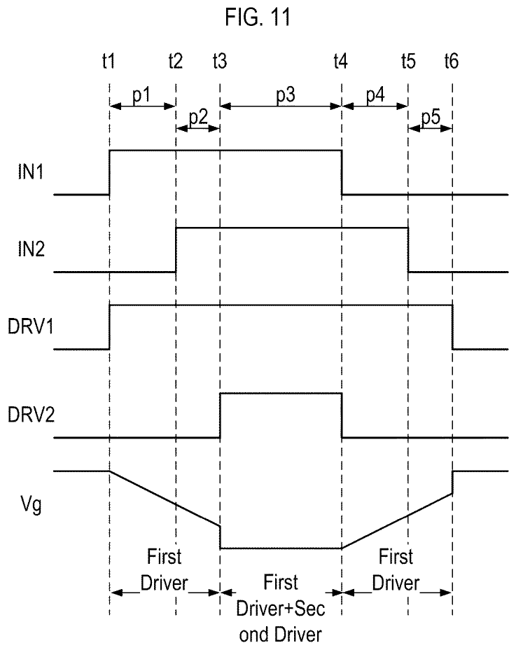

FIG. 11 is a timing diagram of the switching circuit of FIG. 10.

Referring to FIGS. 10 and 11, prior to time t1, both the first input signal IN1 and the second input signal IN2 were at logic low. As a result, the eighth switch M8 was turned on, allowing a pull-up current to precharge the gate voltage Vg, which is the voltage at the driving node Nd, to a specific value.

At time t1, the first input signal IN1 may transition to logic high. At time t2, the second input signal IN2 may transition to logic high. At p1, the first drive signal DRV1 may go high. As a result, the fifth switch M5 may be turned on. As the fifth switch M5 is turned on, current mirrored through the tenth switch M10 may flow from the driving node Nd to the ground. Accordingly, the gate voltage Vg may slightly decrease, and the power switch MP may be slightly turned on.

The power switch MP is turned on based on current control. As a result, the gate voltage Vg may linearly decrease.

The second drive signal DRV2 may go high after a gap of p2 from the first input signal IN1, and only the first driver 110A-2 may operate during p1 and p2.

After time t3, the second drive signal DRV2 is logic high. As a result, the twelfth switch M12 may be turned on in addition to the driving of the first driver 110A-2. Accordingly, the gate voltage Vg may go low, and the power switch MP may be fully turned on. During p3, the first driver 110A-2 and the second driver 130A-2 may drive the power switch MP together.

At time t4, the first input signal IN1 may transition to logic low, and thus, the second drive signal DRV2 may also transition to logic low. During p4, the eighth switch M8 may be turned on. As a result, the power switch MP may be slightly turned off.

At time t5, the second input signal IN2 may also transition to logic low. After a gap of p5, the first drive signal DRV1 may transition to logic low. Accordingly, after time t6, the eighth switch M8 and the eleventh switch M11 may be turned on. As a result, the gate voltage Vg may go high, and the power switch MP may be fully turned off.

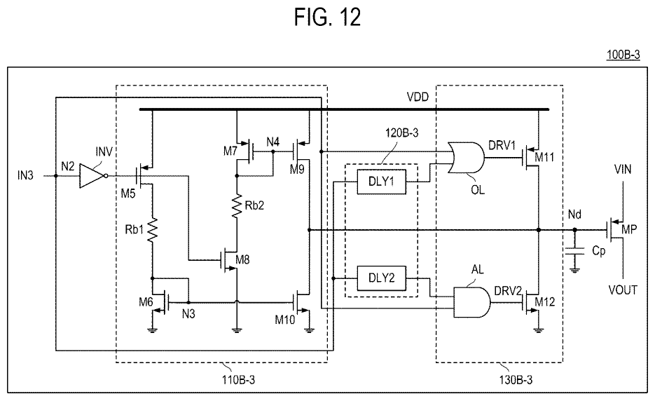

FIG. 12 is a circuit diagram of a switching circuit based on a current-controlled voltage driving scheme according to example embodiments.

Referring to FIG. 12, a switching circuit 100B-3 according to example embodiments may drive a power switch MP based on a third input signal IN3.

For example, a NOT gate INV may invert the third input signal IN3 applied through the second node N2, and the inverted third input signal IN3 may be applied to a gate of the fifth switch M5. The first driver 110B-3 may drive the power switch MP by linearly increasing or decreasing the voltage at the driving node Nd based on the inverted third input signal IN3.

The third input signal IN3 may be applied to each of the delay cells DLY1 and DLY2 included in the delay circuit 120B-3. Accordingly, an OR gate OL may output a first drive signal DRV1 to an eleventh switch M11 through an OR operation on the third input signal IN3 and a delayed input signal. An AND gate AL may output a second drive signal DRV2 to the twelfth switch M12 through an AND operation on the third input signal IN3 and the delayed input signal.

According to example embodiments, the first driver 110B-3 may slightly turn on the power switch MP based on the input signal transitioning to logic high. Then, the first driver 110B-3 and the second driver 130B-3 may fully turn on the power switch MP based on the input signal transitioning to logic high after a time lapse of a delay value or more.

The switching circuit 100B-3 according to example embodiments described above may drive the power switch MP through a common third input signal IN3. Accordingly, even when the number of applied signals is reduced to one, sequential driving of the first driver 110B-3 and the second driver 130B-3 may be performed through the delay circuit 120B-3. As a result, the switching circuit 100B-3 may reduce the effects of momentary current and leakage current.

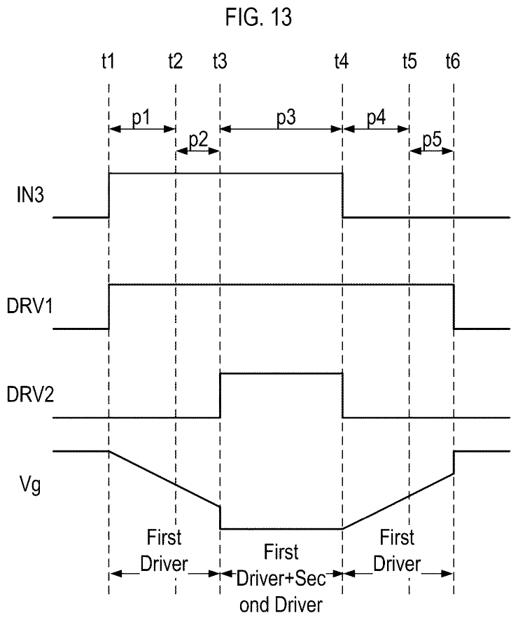

FIG. 13 is a timing diagram of the switching circuit of FIG. 12.

Referring to FIGS. 12 and 13, prior to time t1, the third input signal IN3 was at logic low. As a result, the eighth switch M8 was turned on, and the gate voltage Vg, which is the voltage at the driving node Nd, was precharged to a specific value.

At time t1, the third input signal IN3 may transition to logic high at time t1. At p1, the first drive signal DRV1 may go high. As a result, the fifth switch M5 may be turned on. Accordingly, due to the current flowing to the ground through the tenth switch M10, the gate voltage Vg linearly decreases, and the power switch MP may be slightly turned on.

At time t2 after a gap of p1 from the first input signal IN1, the second drive signal DRV2 may go high. A gap of p2 may have a size greater than or equal to the delay value through the delay circuit 120B-3.

After time t2, since the second drive signal DRV2 is logic high, the twelfth switch M12 may be turned on in addition to the fifth switch M5. Accordingly, the gate voltage Vg may go low, and the power switch MP may be fully turned on. During p2, the first driver 110B-3 and the second driver 130B-3 may drive the power switch MP together.

At time t3, the third input signal IN3 may transition to logic low, and thus, the second drive signal DRV2 may also transition to logic low. During p3, only the eighth switch M8 may be turned on. Accordingly, the power switch MP may be slightly turned off due to current flowing to the driving node Nd through the ninth switch M9.

At time t4 following time t3 after a gap of p3, the first drive signal DRV1 may transition to logic low. Accordingly, after time t4, the eighth switch M8 and the eleventh switch M11 may be turned on. As a result, the gate voltage Vg may go high, and the power switch MP may be fully turned off.

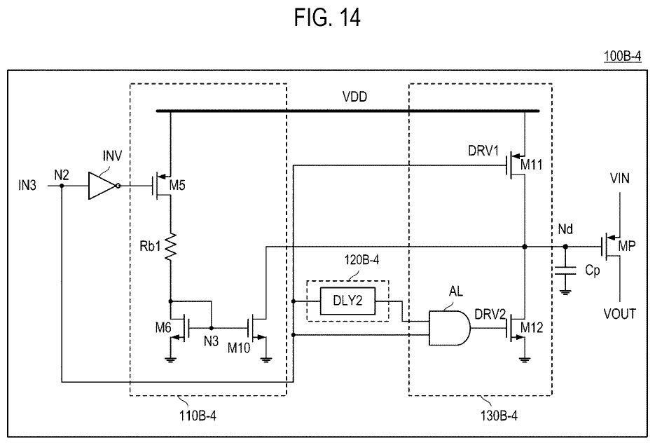

FIG. 14 is a circuit diagram of a switching circuit based on a current-controlled voltage driving scheme according to example embodiments.

Referring to FIG. 14, a switching circuit 100B-4 according to example embodiments may be configured to have an asymmetrical structure, unlike the switching circuit having the symmetrical structure of FIG. 12.

The first driver 110B-4 may include only the components utilized for a pull-down operation in FIG. 12. According to example embodiments, the first driver 110B-4 may include a fifth switch M5, a first bias resistor Rb1, a sixth switch M6, and a tenth switch M10. An inverted third input signal IN3 may be applied to a gate of the fifth switch M5. When the fifth switch M5 is turned on, current may flow through a sixth switch M6 due to a supply voltage VDD and the first bias resistor Rb1. Mirrored current may flow from the driving node Nd to the ground through the tenth switch M10.

Due to an asymmetrical structure, the delay circuit 120B-4 may include only one delay cell DLY2.

The second driver 130B-4 may include an AND gate AL, an eleventh switch M11, and a twelfth switch M12. The AND gate AL may output a second drive signal DRV2 to a gate of the twelfth switch M12 through an AND operation performed on a third input signal IN3 and a delayed input signal. In the asymmetrical structure, the third input signal IN3 may be directly applied to a gate of the eleventh switch M11.

According to example embodiments, even with the asymmetrical structure, a turn-on operation of at least the power switch MP may be the same as that in the symmetrical structure. For example, when a fifth switch M5 of the first driver 110B-4 is turned on, the power switch MP may be slightly turned on due to the current flowing through the tenth switch M10. Then, as a twelfth switch M12 of the second driver 130B-4 is also turned on, the power switch MP may be fully turned on.

In a turn-off operation, only the second driver 130B-4 may drive the power switch MP.

The switching circuit 100B-4 according to example embodiments described above may reduce the implementation complexity through the asymmetrical structure while reducing the effects of momentary current and leakage current on the power switch MP.

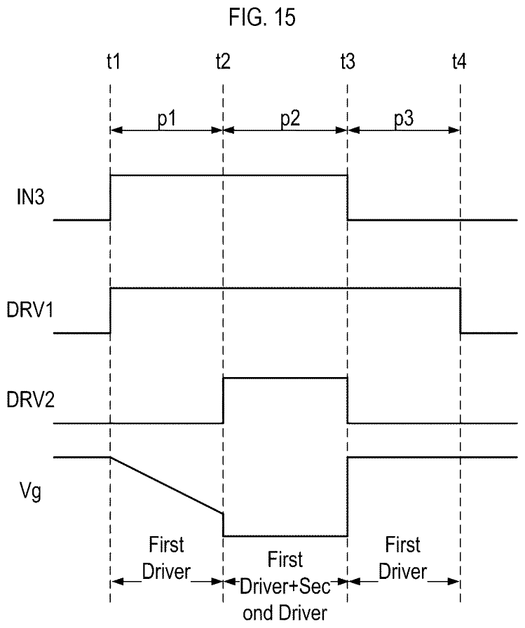

FIG. 15 is a timing diagram of the switching circuit of FIG. 14.

Referring to FIGS. 14 and 15, a turn-on operation of the power switch MP may be the same as in FIG. 13.

At time t1, a third input signal IN3 may transition to logic high. At p1, a first drive signal DRV1 may go high. As a result, only a fifth switch M5 may be turned on. Accordingly, the gate voltage Vg may linearly decrease, and the power switch MP may be slightly turned on. At time t2 after a gap of p1 from the first input signal IN1, the second drive signal DRV2 may go high. At p2, a twelfth switch M12 may be turned on in addition to the fifth switch M5. Accordingly, the gate voltage Vg may go low, and the power switch MP may be fully turned on.

At time t3, the third input signal IN3 may transition to logic low, and thus, the second drive signal DRV2 may also transition to logic low. Unlike an embodiment illustrated in FIG. 13, only the eleventh switch M11 of the second driver 130B-4 may be turned on during p3. As a result, the power switch MP may be immediately fully turned off. At time t4 following time t3 after a gap of p3, the first drive signal DRV1 may transition to logic low.

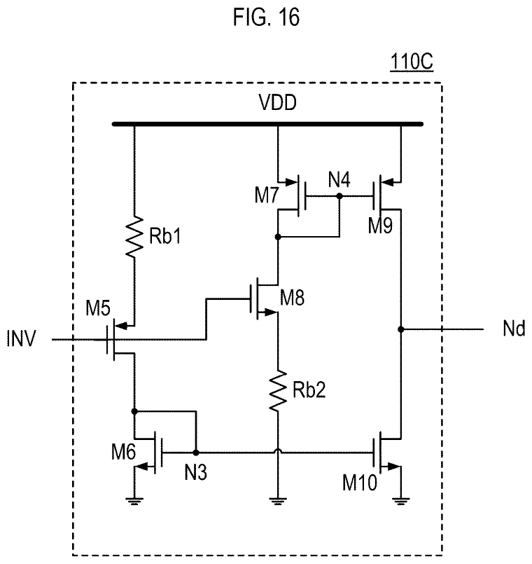

FIG. 16 is a circuit diagram of a first driver according to example embodiments.

Referring to FIG. 16, in a first driver 110C included in switching circuits operating based on a current-controlled voltage driving scheme according to example embodiments described above (for example, FIGS. 10, 12, and 14), locations of the resistors Rb1 and Rb2 may be changed.

For example, one end of the first bias resistor Rb1 may be applied with a supply voltage VDD, and the other end may be connected to a source of the fifth switch M5. Also, one end of the second bias resistor Rb2 may be connected to a source of the eighth switch M8, and the other end may be grounded. Even in this case, similarly to the first driver according to example embodiments described above, the first driver 110C may perform a current-controlled driving operation on the driving node Nd.

According to example embodiments, a location of one of the first bias resistor Rb1 and the second bias resistor Rb2 may be changed (for example, the first bias resistor Rb1 may be connected to a drain of the fifth switch M5, or the second bias resistor Rb2 may be connected to a source of the eighth switch M8).

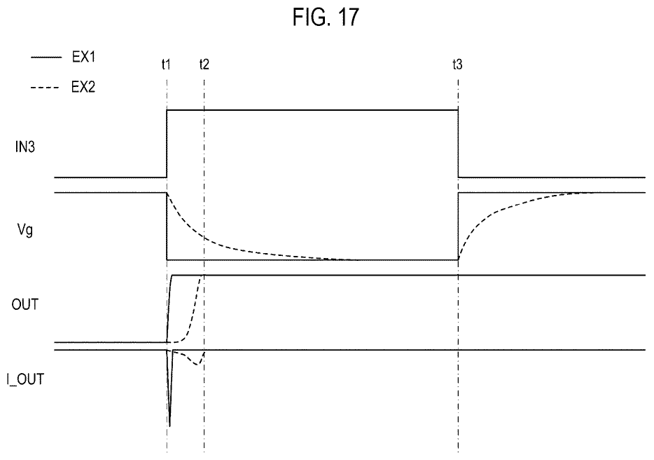

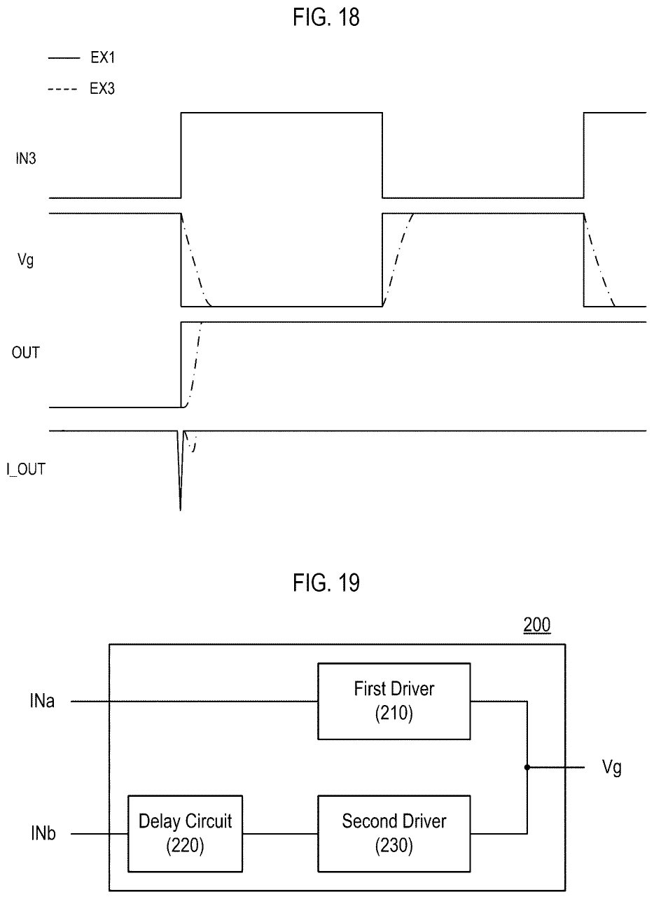

FIGS. 17 and 18 are diagrams illustrating operation waveforms of a switching circuit according to example embodiments. Referring to FIGS. 17 and 18, Example 1 (EX1) is a switching circuit implemented with a general driver, Example 2 (EX2) is a switching circuit based on an RC filter according to example embodiments described above, and Example 3 (EX3) is a switching circuit based on a current-controlled voltage driving scheme according to example embodiments described above.

Referring to FIG. 17, when the third input signal IN3 goes high at time point t1, the gate voltage Vg may immediately transition to logic low in Example 1, but the gate voltage Vg may decrease slightly in Example 3. Therefore, a voltage at opposite ends of the power switch OUT may increase rapidly in Example 1, whereas it may increase relatively slowly in Example 2. Similarly, current I_OUT flowing through opposite ends of the power switch may rise rapidly in Example 1, whereas it may rise relatively slowly due to the driving of the second driver.

FIG. 18 also illustrates waveforms similar to those of FIG. 17. However, Example 3 of FIG. 18 is based on a current-controlled voltage driving scheme. As a result, the gate voltage Vg may linearly increase or decrease. The voltage OUT and current I_OUT at opposite ends of the power switch may be slowly changed in Example 3.

FIG. 19 is a block diagram of a driving circuit according to example embodiments.

Referring to FIG. 19, a driving circuit 200 according to example embodiments may include a first driver 210, a delay circuit 220, and a second driver 230. The first driver 210, the delay circuit 220, and the second driver 230 may be configured or operated based on the above-described embodiments (for example, FIGS. 4, 6, 8, 10, 12, 14, and 16).

The driving circuit 200 may drive a switching signal Vg based on one or more input signals. For example, the driving circuit 200 may operate based on two input signals INa and INb. In example embodiments, when the two input signals INa and INb are the same, the driving circuit 200 may operate based on a single input signal.

The first driver 210 according to example embodiments may drive a switching signal Vg based on one or more input signals. The delay circuit 220 may output a delayed input signal in which a single input signal INb is delayed by a delay value. The second driver 230 may drive the switching signal Vg based on the delayed input signal.

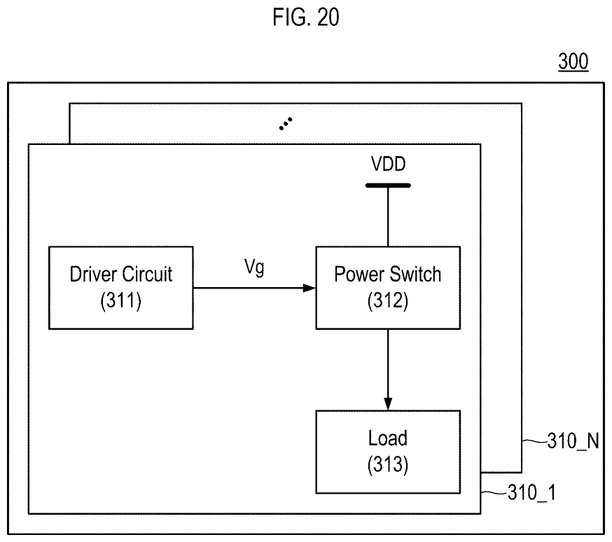

FIG. 20 is a diagram illustrating an electronic device 300 according to example embodiments.

Referring to FIG. 20, an electronic device 300 according to example embodiments may include one or more power control devices 310_1 to 310_N, where N is a positive integer. Each of the power control devices 310_1 to 310_N may include a driving circuit 311, a power switch 312, and a load 313.

The driving circuit 311 and the power switch 312 may be configured or operated according to example embodiments described above (for example, FIGS. 1 to 19). The driving circuit 311 may drive a switching signal Vg of the power switch 312 to turn on or off the power switch 312.

The load 313 may be supplied with a voltage from the power switch 312 when the power switch 312 is turned on. The load 313 may operate based on the power according to the supplied voltage. For example, the load 313 may include various intellectual property (IP) blocks operating based on the power.

As process technology scales down, leakage current of the load 313 may increase. As a result, the power switch 312 may selectively supply power to the load 313 to reduce the leakage current of the load 313. In addition, the driving circuit 311 according to example embodiments may reduce the effects of the leakage current of the power switch 312 by using a plurality of drivers having different output impedances when turning on the power switch 312. Accordingly, a voltage provided to the load may be prevented from decreasing.

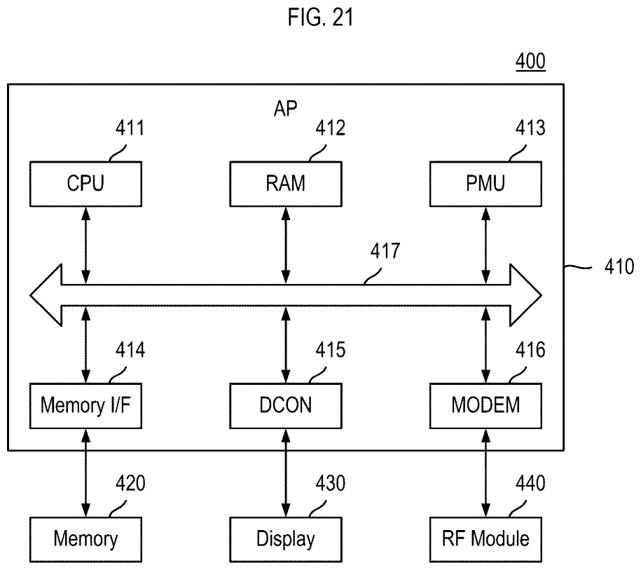

FIG. 21 is a diagram illustrating a mobile terminal according to example embodiments.

Referring to FIG. 21, a mobile terminal 400 may include an application processor 410 (AP), a memory 420, a display 430, and a radio frequency (RF) module 440. The mobile terminal 400 may further include various components such as, for example, a lens, a sensor, and an audio module.

The AP 410 may be implemented as a system-on-chip (SoC) and may include, for example, a central processing unit (CPU) 411, a random access memory (RAM) 412, a power management unit (PMU) 413, a memory interface (Memory I/F) 414, a display controller (DCON) 415, a modem (MODEM) 416, and a system bus 417. The AP 410 may further include various other IP blocks. The AP 410 may be referred to as ModAP because functions of a modem chip may be integrated therein.

The CPU 411 may control the overall operation of the AP 410 and the mobile terminal 400. The CPU 411 may control an operation of each component of the AP 410. The CPU 411 may be implemented as a multi-core CPU. A multi-core CPU is a single computing component having two or more independent cores.

The RAM 412 may temporarily store, for example, programs, data, or instructions. For example, programs and/or data stored in the memory 420 may be temporarily stored in the RAM 412 under the control of the CPU 411 or a booting code. The RAM 412 may be implemented as, for example, a DRAM or an SRAM.

The PMU 413 may manage power of each component of the AP 410. Also, the PMU 413 may determine an operating status of each component of the AP 410 and control an operation thereof.

The memory interface 414 may control the overall operation of the memory 420 and may control data exchange between each component of the AP 410 and the memory 420. The memory interface 414 may write data in the memory 420 or read data from the memory 420 according to a request of the CPU 411.

For reference, supplying power to the plurality of IP blocks included in the AP 410 may be controlled through a driving circuit and a switching circuit according to example embodiments described above.

The display controller 415 may transmit video data to be displayed on the display 430 to the display 430. The display 430 may be implemented as, for example, a flat panel display such as a liquid crystal display (LCD), an organic light emitting diode (OLED), or a flexible display. For wireless communication, the modem 416 may modulate data to be transmitted, in order to suit a wireless environment, and may recover received data. The modem 416 may perform digital communication with the RF module 440.

The RF module 440 may convert a high-frequency signal, received via an antenna, into a low-frequency signal, and transmit the low-frequency signal to the modem 416. The RF module 440 may convert a low-frequency signal, received from the modem 416, into a high-frequency signal, and transmit the high-frequency signal to the outside of the mobile terminal 400 via the antenna. The RF module 440 may also amplify or filter a signal.

As is traditional in the field of the present disclosure, example embodiments are described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, etc., which may be formed using semiconductor-based fabrication techniques or other manufacturing technologies. In the case of the blocks, units and/or modules being implemented by microprocessors or similar, they may be programmed using software (e.g., microcode) to perform various functions discussed herein and may optionally be driven by firmware and/or software. Alternatively, each block, unit and/or module may be implemented by dedicated hardware, or as a combination of dedicated hardware to perform some functions and a processor (e.g., one or more programmed microprocessors and associated circuitry) to perform other functions.

As set forth above, according to example embodiments, a driving circuit which may reduce effects of gate leakage current and a switching circuit including the same may be provided.

While the present disclosure has been particularly shown and described with reference to embodiments thereof, it will be understood by those of ordinary skill in the art that various changes in form and detail may be made therein without departing from the spirit and scope of the present disclosure as defined by the following claims.

What is claimed is:

1. A switching circuit, comprising:
a power switch;
a first driver configured to drive the power switch based on a first input signal,
wherein the first driver has a first driving strength and is configured to drive the power switch in a first stage of operation;
a delay circuit configured to output a delayed input signal,
wherein the delayed input signal is delayed by a delay value relative to a second input signal; and
a second driver configured to drive the power switch based on the delayed input signal,
wherein the second driver has a second driving strength higher than the first driving strength and is configured to drive the power switch in a second stage of operation, which is subsequent to the first stage of operation.

2. The switching circuit of claim 1, wherein
the power switch has a source that receives an input voltage, a gate connected to a drive node connected to the first driver and the second driver, and a drain through which an output voltage is output.

3. The switching circuit of claim 1, wherein
the second input signal is a signal delayed by a set time value from the first input signal.

4. The switching circuit of claim 1, wherein
the first driver has a higher output impedance than the second driver.

5. The switching circuit of claim 1, wherein
the first driver partially turns on the power switch in the first stage of operation in response to the first input signal being logic high and the second input signal being logic low.

6. The switching circuit of claim 5, wherein
the first and second drivers fully turn on the power switch in the second stage of operation in response to the first and second input signals being logic high and a time corresponding to at least the delay value having elapsed after the second input signal transitions to logic high.

7. The switching circuit of claim 1, wherein
the first driver partially turns off the power switch in the first stage of operation in response to the first input signal being logic low and the second input signal being logic high.

8. The switching circuit of claim 7, wherein
the first and second drivers fully turn off the power switch in the second stage of operation in response to the first and second input signals being logic low and a time corresponding to at least the delay value having elapsed after the second input signal transitions to logic low.

9. The switching circuit of claim 2, wherein
the first driver comprises:
a first resistor and a second resistor connected to the drive node;
a first P-type transistor having a source that receives a supply voltage, a gate that receives the first input signal, and a drain connected to the first resistor; and
a first N-type transistor having a drain connected to the second resistor, a gate that receives the first input signal, and a source connected to a ground.

10. The switching circuit of claim 9, wherein
the second driver comprises:
a first logic gate configured to output a first drive signal by performing an OR operation on the first input signal and the delayed input signal;
a second logic gate configured to output a second drive signal by performing an AND operation on the first input signal and the delayed input signal;
a second P-type transistor having a source connected to the supply voltage, a gate that receives the first drive signal, and a drain connected to the drive node; and
a second N-type transistor having a drain connected to the drive node, a gate that receives the second drive signal, and a source connected to the ground.

11. The switching circuit of claim 2, further comprising:
a NOT gate configured to invert a phase of the first input signal,
wherein
the first driver comprises:
a first resistor and a second resistor connected to the drive node;
a first P-type transistor having a source that receives a supply voltage, a gate connected to the NOT gate, and a drain connected to the first resistor;
a second P-type transistor having a source that receives the supply voltage and a gate and a drain connected to the second resistor;
a third P-type transistor having a source that receives the supply voltage, a gate connected to the second resistor, and a drain connected to the drive node;
a first N-type transistor having a drain and a gate connected to the first resistor and a source connected to a ground;
a second N-type transistor having a drain connected to the second resistor, a gate connected to the NOT gate, and a source connected to the ground; and
a third N-type transistor having a drain connected to the drive node, a gate connected to the first resistor, and a source connected to the ground.

12. The switching circuit of claim 11, wherein
the second driver comprises:
a first logic gate configured to output a first drive signal by performing an OR operation on the first input signal and the delayed input signal;
a second logic gate configured to output a second drive signal by performing an AND operation on the first input signal and the delayed input signal;
a fourth P-type transistor having a source that receives the supply voltage, a gate that receives the first drive signal, and a drain connected to the drive node; and
a fourth N-type transistor having a drain connected to the drive node, a gate that receives the second drive signal, and a source connected to the ground.

13. A switching circuit, comprising:
a power switch;
a first driver configured to drive the power switch based on an input signal,
wherein the first driver has a first driving strength and is configured to drive the power switch in a first stage of operation;
a delay circuit configured to output a delayed input signal,
wherein the delayed input signal is delayed by a delay value relative to the input signal; and
a second driver configured to drive the power switch based on the delayed input signal,
wherein the second driver has a second driving strength higher than the first driving strength and is configured to drive the power switch in a second stage of operation, which is subsequent to the first stage of operation.

14. The switching circuit of claim 13, wherein
the power switch has a source that receives an input voltage, a gate connected to a drive node connected to the first driver and the second driver, and a drain through which an output voltage is output.

15. The switching circuit of claim 13, wherein
the first driver partially turns on the power switch in the first stage of operation in response to the input signal transitioning to logic high, and
the first driver and the second driver fully turn on the power switch in the second stage of operation in response to a time corresponding to at least the delay value having elapsed after the input signal transitions to logic high.

16. The switching circuit of claim 14, wherein
the first driver comprises:
a resistor connected to the drive node; and
a first N-type transistor having a drain connected to the resistor, a gate that receives the input signal, and a source connected to a ground, and
the second driver comprises:
a logic gate configured to output a drive signal by performing an AND operation on the input signal and the delayed input signal;
a P-type transistor having a source that receives a supply voltage, a gate that receives the input signal, and a drain connected to the drive node; and
a second N-type transistor having a drain connected to the drive node, a gate that receives the drive signal, and a source connected to the ground.

17. The switching circuit of claim 14, wherein
the first driver comprises:
a first resistor and a second resistor connected to the drive node;
a first P-type transistor having a source connected to a supply voltage, a gate that receives the input signal, and a drain connected to the first resistor; and
a first N-type transistor having a drain connected to the second resistor, a gate that receives the input signal, and a source connected to a ground, and
the second driver comprises:
a first logic gate configured to output a first drive signal by performing an OR operation on the input signal and the delayed input signal;
a second logic gate configured to output a second drive signal by performing an AND operation on the input signal and the delayed input signal;
a second P-type transistor having a source that receives the supply voltage, a gate that receives the first drive signal, and a drain connected to the drive node; and
a second N-type transistor having a drain connected to the drive node, a gate that receives the second drive signal, and a source connected to the ground.

18. The switching circuit of claim 14, further comprising:
a NOT gate configured to invert a phase of the input signal,
wherein
the first driver comprises:
a first P-type transistor having a source that receives a supply voltage, a gate connected to the NOT gate, and a drain connected to a resistor;
a first N-type transistor having a drain and a gate connected to the resistor and a source connected to a ground; and
a second N-type transistor having a drain connected to the drive node, a gate connected to the resistor, and a source connected to the ground, and
the second driver comprises:
a logic gate configured to output a drive signal by performing an AND operation on the input signal and the delayed input signal;
a second P-type transistor having a source that receives the supply voltage, a gate that receives the input signal, and a drain connected to the drive node; and
a third N-type transistor having a drain connected to the drive node, a gate that receives the drive signal, and a source connected to the ground.

19. The switching circuit of claim 14, further comprising:
a NOT gate configured to invert a phase of the input signal,
wherein
the first driver comprises:
a first P-type transistor having a source that receives a supply voltage, a gate connected to the NOT gate, and a drain connected to a first resistor;
a second P-type transistor having a source that receives the supply voltage and a gate and a drain connected to a second resistor;
a third P-type transistor having a source that receives the supply voltage, a gate connected to the second resistor, and a drain connected to the drive node;
a first N-type transistor having a drain and a gate connected to the first resistor and a source connected to a ground;
a second N-type transistor having a drain connected to the second resistor, a gate connected to the NOT gate, and a source connected to the ground; and
a third N-type transistor having a drain connected to the drive node, a gate connected to the first resistor, and a source connected to the ground, and
the second driver comprises:
a first logic gate configured to output a first drive signal by performing an OR operation on the input signal and the delayed input signal;
a second logic gate configured to output a second drive signal by performing an AND operation on the input signal and the delayed input signal;
a fourth P-type transistor having a source that receives the supply voltage, a gate that receives the first drive signal, and a drain connected to the drive node; and
a fourth N-type transistor having a drain connected to the drive node, a gate that receives the second drive signal, and a source connected to the ground.

20. A driving circuit, comprising:
a first driver configured to drive a switching signal based on a first input signal,
wherein the first driver has a first driving strength and is configured to drive the switching signal in a first stage of operation;
a delay circuit configured to output a delayed input signal,
wherein the delayed input signal is delayed by a delay value relative to a second input signal; and
a second driver configured to drive the switching signal based on the delayed input signal,
wherein the second driver has a second driving strength higher than the first driving strength and is configured to drive the switching signal in a second stage of operation, which is subsequent to the first stage of operation.
